(19) United States
(12) Patent Application Publication
(10) Pub. No.: US 2026/0028716 A1
(43) Pub. Date: Jan. 29, 2026

(54) METHOD OF MAKING FLAT POTASSIUM-INTERCALATED METALLIC TRANSITION METAL CHALCOGEN NANOARRAYS

(71) Applicant: CITY UNIVERSITY OF HONG KONG, HONG KONG (CN)

(72) Inventors: HUA ZHANG, HONG KONG (CN); WEI ZHAI, HONG KONG (CN); BANLAN CHI, HONG KONG (CN)

(73) Assignee: CITY UNIVERSITY OF HONG KONG, HONG KONG (CN)

(21) Appl. No.: 18/785,193

(22) Filed: Jul. 26, 2024

(51) Int. Cl. C23C 16/30; C23C 16/56; H01L 29/45

(52) U.S. Cl. CPC C23C 16/305; C23C 16/56; H10D 64/62

(57) ABSTRACT

The method of making flat potassium-intercalated metallic transition metal chalcogen (K-TMC) nanoarrays produces materials which may be used as electrodes for transistors and the like. A powdered transition metal dichalcogenide (TMD) is mixed with potassium carbonate (K₂CO₃) to form a mixture. A quantity of the mixture is loaded into a crucible, which is then covered with a substrate. The crucible is then heated in a chemical vapor deposition tube furnace to form a potassium-intercalated metallic transition metal chalcogen (K-TMC) nanoarray on the substrate through chemical vapor deposition. The substrate and the K-TMC nanoarray formed thereon are removed from the chemical vapor deposition tube furnace and washed with deionized water to remove any absorbed salts.

### BACKGROUND

### Field

The disclosure of the present patent application relates to the preparation of electrodes, and particularly to a method of making flat potassium-intercalated metallic transition metal chalcogen (K-TMC) nanoarrays for use as electrodes in transistor contacts and the like.

### Description of Related Art

Two-dimensional (2D) transition metal dichalcogenides (TMDs) are of great interest for use as channel materials in electronic components, such as electrodes in field effect transistors (FETs). 2D TMDs have potential as channel materials due to their atomically thin sizes (in terms of thickness) and their dangling-bond-free surfaces. However, thus far, the performance of electronics fabricated with 2D TMDs has been negatively affected by the interfaces between the 2D TMDs and the three-dimensional (3D) metals evaporated thereon. During the thermal evaporation process, the induced chemical bonding between TMDs and evaporated metals, and also the diffusion of metals into the TMDs, can lead to a Fermi-level pinning at the semiconductor-metal interface (SMI). Such pinning can result in high contact resistance. Recent studies have demonstrated that the van der Waals integration of 2D semiconducting TMDs and metallic electrodes can avoid surface damage and provide an ideal SMI, improving device performance based on 2D semiconducting TMDs.

As a group of metallic one-dimensional (1D) nanomaterials, transition metal chalcogenide (TMC)-based materials hold great potential for use as the metallic electrodes in TMD-TMC heterostructures for high-performance electronics. Electron beam irradiation and heat treatment have been used to construct TMD-TMC heterostructures, however, such heterostructures have only been formed in limited areas, thus making these techniques inapplicable for the actual production of electronics. TMC nanowires have also been synthesized using chemical vapor deposition (CVD), however, thus far, such synthesized TMC nanowires suffer from wrinkled or bent surfaces that cannot form a tight contact when integrated with semiconducting TMDs.

In addition to the above, the Schottky barrier height (ϕ_{SB}) is highly dependent on the work function difference between TMC and TMDs. However, the work function of TMC has not been able to be tuned, thus requiring different techniques to be considered for manufacturing TMD-TMC heterostructures for differing purposes. Thus, a method of making flat potassium-intercalated metallic transition metal chalcogen nanoarrays solving the aforementioned problems is desired.

### SUMMARY

The method of making flat potassium-intercalated metallic transition metal chalcogen (K-TMC) nanoarrays produces materials which may be used as electrodes for transistors and the like. By varying the composition of precursor materials used in the method, the resultant product can be tuned to produce an ohmic contact or a Schottky contact, as non-limiting examples. A powdered transition metal dichalcogenide (TMD) is mixed with potassium carbonate (K₂CO₃) to form a mixture. Non-limiting examples of TMDs which may be used include MoS₂, MoSe₂, MoSₓSe₍₁₋ₓ₎, MoTe₂, WSe₂ and WTe₂, where x ranges between 0 and 1. A quantity of the mixture is loaded into a crucible, which is then covered with a substrate. As a non-limiting example, the crucible may be a quartz crucible and the substrate may be a mica substrate with a freshly exfoliated surface. The crucible is then heated in a chemical vapor deposition tube furnace to form a potassium-intercalated metallic transition metal chalcogen (K-TMC) nanoarray on the mica substrate through chemical vapor deposition. The mica substrate and the K-TMC nanoarray formed thereon are removed from the chemical vapor deposition tube furnace and washed with deionized water to remove any absorbed salts.

These and other features of the present subject matter will become readily apparent upon further review of the following specification.

### BRIEF DESCRIPTION OF DRAWINGS

FIG. 1A is an optical microscope image of a K—MoS nanoarray formed on a mica substrate using the method of making flat potassium-intercalated metallic transition metal chalcogen (K-TMC) nanoarrays.

FIG. 1B is an optical microscope image of a K—MoSe nanoarray formed on a mica substrate using the method of making flat potassium-intercalated metallic transition metal chalcogen (K-TMC) nanoarrays.

FIG. 1C is an optical microscope image of a K—MoSeₓS₍₁₋ₓ₎ nanoarray formed on a mica substrate using the method of making flat potassium-intercalated metallic transition metal chalcogen (K-TMC) nanoarrays.

FIG. 1D is an optical microscope image of a K—WSe nanoarray formed on a mica substrate using the method of making flat potassium-intercalated metallic transition metal chalcogen (K-TMC) nanoarrays.

FIG. 1E is an optical microscope image of a K—MoTe nanoarray formed on a mica substrate using the method of making flat potassium-intercalated metallic transition metal chalcogen (K-TMC) nanoarrays.

FIG. 1F is an optical microscope image of a K—CoS nanoarray formed on a mica substrate using the method of making flat potassium-intercalated metallic transition metal chalcogen (K-TMC) nanoarrays.

FIG. 2A is a transmission electron microscope (TEM) image of a K—MoSe nanoarray formed on a mica substrate using the method of making flat potassium-intercalated metallic transition metal chalcogen (K-TMC) nanoarrays.

FIG. 2B is a high-angle annular dark-field scanning transmission electron microscopy (HAADF-STEM) image of the K—MoSe nanoarray formed on the mica substrate using the method of making flat potassium-intercalated metallic transition metal chalcogen (K-TMC) nanoarrays. The inset of FIG. 2B shows a simulated HAADF-STEM image of monoclinic K₂Mo₆Se₆.

FIG. 2C is a HAADF-STEM image of a cross-section of the K—MoSe nanoarray formed on the mica substrate using the method of making flat potassium-intercalated metallic transition metal chalcogen (K-TMC) nanoarrays.

FIG. 2D is an enlarged view of the HAADF-STEM image of FIG. 2C.

FIG. 2E shows a further enlargement of the HAADF-STEM image of FIG. 2C.

FIG. 2F shows a simulated HAADF-STEM image of K₂Mo₆Se₆ on the same scale as the image of FIG. 2E.

FIG. 2G is a scanning transmission electron microscope (STEM) image of a cross-section of the K—MoSe nanoarray formed on the mica substrate using the method of making flat potassium-intercalated metallic transition metal chalcogen (K-TMC) nanoarrays.

FIG. 2H is an elemental mapping image for potassium (K) for the STEM image of FIG. 2G.

FIG. 2I is an elemental mapping image for molybdenum (Mo) for the STEM image of FIG. 2G.

FIG. 2J is an elemental mapping image for selenium (Se) for the STEM image of FIG. 2G.

FIG. 3A is an optical microscope image of a K—MoSe nanoarray formed on a mica substrate using the method of making flat potassium-intercalated metallic transition metal chalcogen (K-TMC) nanoarrays.

FIG. 3B is an atomic force microscope (AFM) image of the K—MoSe nanoarray formed on the mica substrate using the method of making flat potassium-intercalated metallic transition metal chalcogen (K-TMC) nanoarrays.

FIG. 3C is a Raman mapping image of the K—MoSe nanoarray formed on the mica substrate using the method of making flat potassium-intercalated metallic transition metal chalcogen (K-TMC) nanoarrays.

FIG. 3D shows the Raman spectra of the K—MoSe nanoarray formed on the mica substrate using the method of making flat potassium-intercalated metallic transition metal chalcogen (K-TMC) nanoarrays.

FIG. 3E shows angle-resolved polarized Raman spectroscopy (ARPRS) results for the K—MoSe nanoarray formed on the mica substrate using the method of making flat potassium-intercalated metallic transition metal chalcogen (K-TMC) nanoarrays.

FIG. 3F illustrates the peak intensities of the Raman spectra of the K—MoSe nanoarray along four different directions.

FIG. 3G shows X-ray photoelectron spectroscopy (XPS) spectra for the K—MoSe nanoarray for the Mo 3d_{3/2} and Mo 3d_{5/2} orbital peaks.

FIG. 3H shows X-ray photoelectron spectroscopy (XPS) spectra for the K—MoSe nanoarray for the Se 3d_{3/2} and Se 3d_{5/2} orbital peaks.

FIG. 3I shows X-ray photoelectron spectroscopy (XPS) spectra for the K—MoSe nanoarray for the K 2p_{1/2} and K 2p_{3/2} orbital peaks.

FIG. 4A is a plot showing the work function of K—MoSₓSe₍₁₋ₓ₎ for values of x between 0.0 and 1.00.

FIG. 4B shows the band structure for a K—MoSₓSe₍₁₋ₓ₎-MoS₂ heterostructure for x=0.0.

FIG. 4C shows the band structure for a K—MoSₓSe₍₁₋ₓ₎-MoS₂ heterostructure for x>0.0.

FIG. 4D diagrammatically illustrates a field-effect transistor (FET) with K-TMC as an electrode material.

FIG. 4E shows the Ids-Vas curve for K—MoSe.

FIG. 4F shows the I_{ds}−V_{gs} curves for K—MoSe.

FIG. 4G shows an optical microscope image of an FET assembled from a K—MoSe-MoS₂ heterostructure.

FIG. 4H shows a scanning electron microscope (SEM) image of the FET of FIG. 4G.

FIG. 4I is a graph showing the transfer curves of the FET assembled from the K—MoSe-MoS₂ heterostructure.

FIG. 4J is a graph showing the output curves of the FET assembled from the K—MoSe-MoS₂ heterostructure.

Similar reference characters denote corresponding features consistently throughout the attached drawings.

### DETAILED DESCRIPTION

The method of making flat potassium-intercalated metallic transition metal chalcogen (K-TMC) nanoarrays produces materials which may be used as electrodes for transistors and the like. By varying the composition of precursor materials used in the method, the resultant product can be tuned to produce an ohmic contact or a Schottky contact, as non-limiting examples. A powdered transition metal dichalcogenide (TMD) is mixed with potassium carbonate (K₂CO₃) to form a mixture. Non-limiting examples of TMDs which may be used include MoS₂, MoSe₂, MoSₓSe₍₁₋ₓ₎, MoTe₂, WSe₂ and WTe₂, where x ranges between 0 and 1. A quantity of the mixture is loaded into a crucible, which is then covered with a substrate. As a non-limiting example, the crucible may be a quartz crucible and the substrate may be a mica substrate with a freshly exfoliated surface. In experiments, 20 mg of the mixture was loaded into such a crucible and covered with a mica substrate with a freshly exfoliated surface.

The crucible is then heated in a chemical vapor deposition (CVD) tube furnace to form a potassium-intercalated metallic transition metal chalcogen (K-TMC) nanoarray on the mica substrate through chemical vapor deposition. In experiments, the crucible was heated in a CVD tube furnace with an inner diameter of 2.0 cm. The atmosphere inside the CVD tube furnace may be evacuated using a vacuum pump or the like, following insertion of the crucible therein but prior to the heating of the crucible. Prior to the heating of the crucible, the CVD tube furnace may be filled with a gaseous mixture of hydrogen (H₂) and argon (Ar). In experiments, the CVD tube furnace was evacuated and refilled at least three times with the gaseous mixture of hydrogen and argon, with the hydrogen filling the CVD tube furnace at a rate of 10 standard cubic centimeters per minute (sccm) and with the argon filling the CVD tube furnace at a rate of 90 sccm.

The crucible may be heated in the chemical vapor deposition tube furnace at a temperature between 850° C. and 900° C. and maintained at this temperature for approximately 10 minutes. In experiments, following the CVD reaction, the crucible was quickly moved from the heating zone within the CVD tube furnace and the flow of the gaseous mixture of hydrogen and argon was not turned off until the CVD tube furnace cooled to room temperature. The mica substrate and the K-TMC nanoarray formed thereon are then removed from the chemical vapor deposition tube furnace and washed with deionized (DI) water or the like to remove any absorbed salts.

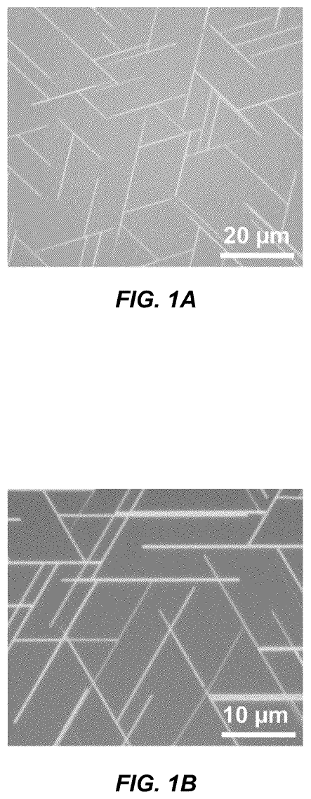

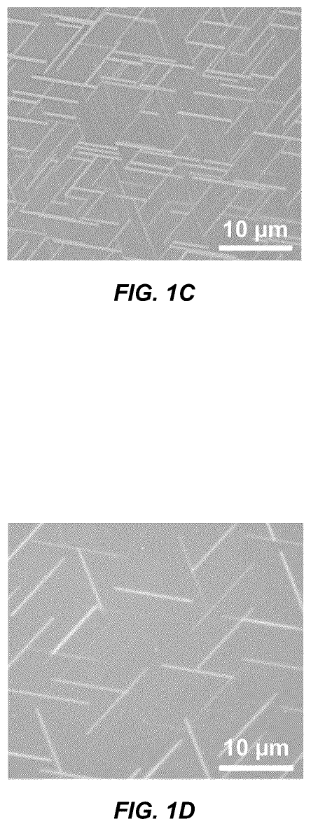

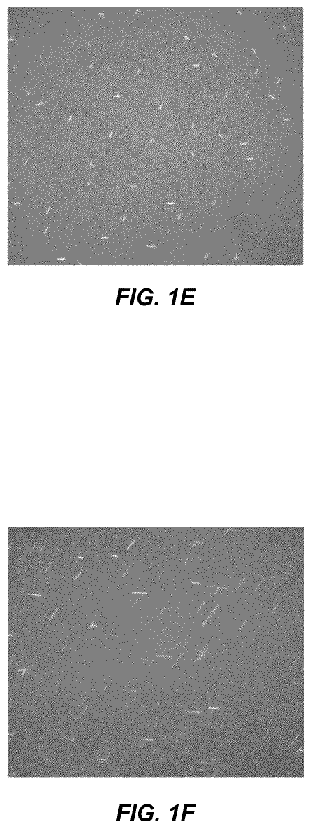

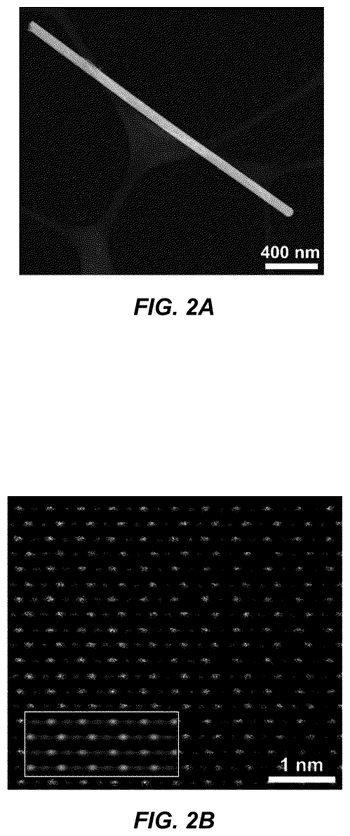

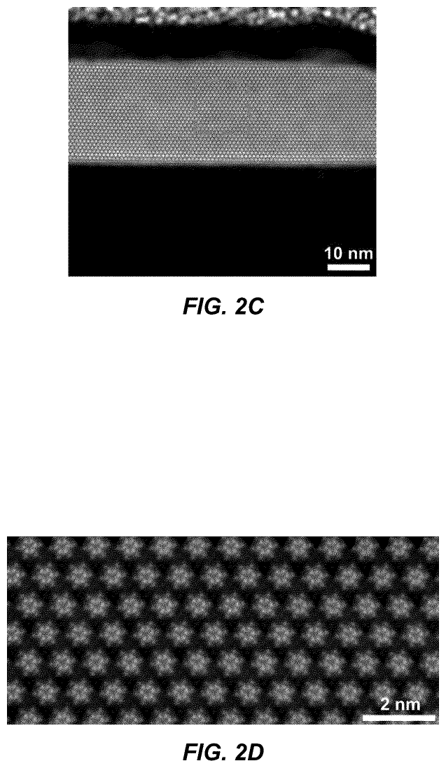

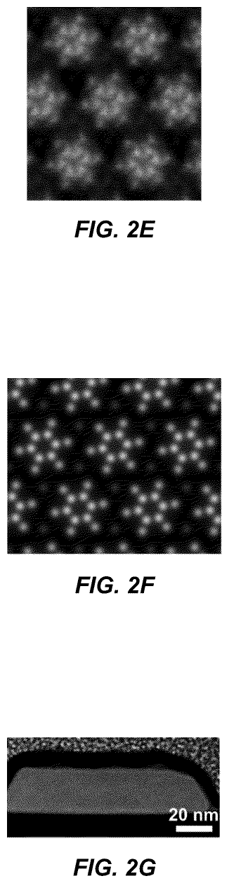

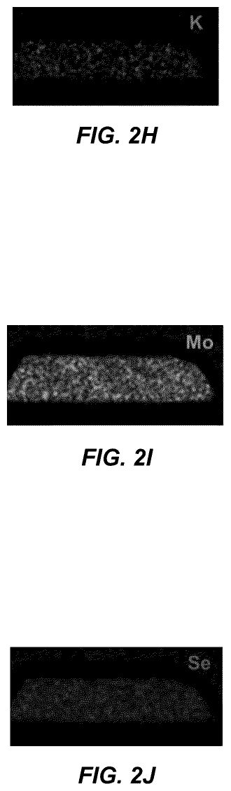

FIGS. 1A, 1B, 1C, 1D, 1E and 1F respectively show optical microscope images on the order of ˜10 μm for K—MoS, K—MoSe, K—MoSeₓS₍₁₋ₓ₎, K—WSe, K—MoTe and K—CoS nanoarrays formed on mica substrates using the method described above. The synthesized K—MoSe nanoarrays were also characterized by transmission electron microscopy (TEM) and high-angle annular dark-field scanning transmission electron microscopy (HAADF-STEM). The TEM image of FIG. 2A shows that the prepared K—MoSe has a straight morphology. In FIG. 2B, the HADDF-STEM image of the synthesized K—MoSe nanoarrays can be seen as matching well with a simulated HAADF-STEM image (shown in the inset of FIG. 2B) of monoclinic K₂Mo₆Se₆ (referred to herein as “K—MoSe”).

To further confirm the crystal structure of the synthesized nanowires, the prepared sample of K—MoSe was cut using a focused ion beam and the cross-section of the sample was characterized using HAADF-STEM, as shown in FIG. 2C. FIG. 2D is an enlarged view of the HAADF-STEM image of FIG. 2C. FIG. 2D clearly shows that the synthesized nanowires consist of star-shaped Mo₆Se₆ unit clusters with potassium ions intercalated between adjacent clusters. FIG. 2E shows a further enlargement of the same region, showing a close match with a simulated HAADF-STEM image of K₂Mo₆Se₆ (shown in FIG. 2F). FIG. 2G is a scanning transmission electron microscope (STEM) image of a cross-section of the synthesized nanoarray, and the elemental mapping images of FIGS. 2H, 2I and 2J show the even distribution of the K, Mo and Se signals, respectively, within the nanowire cross-section.

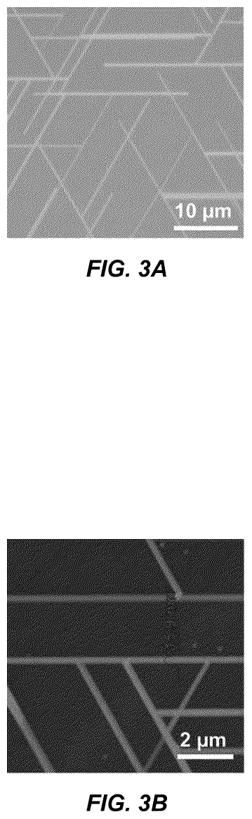

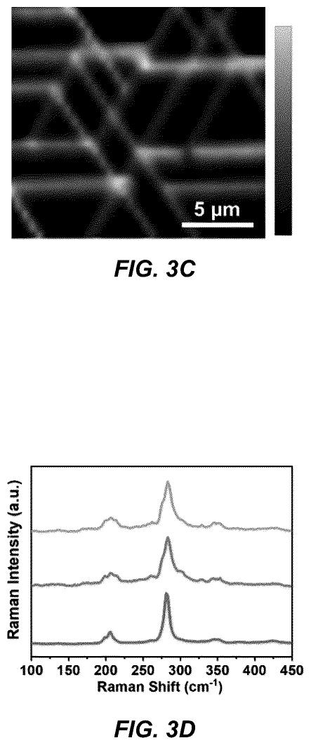

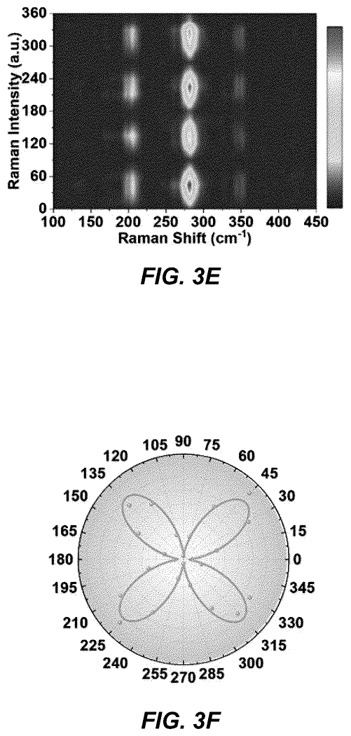

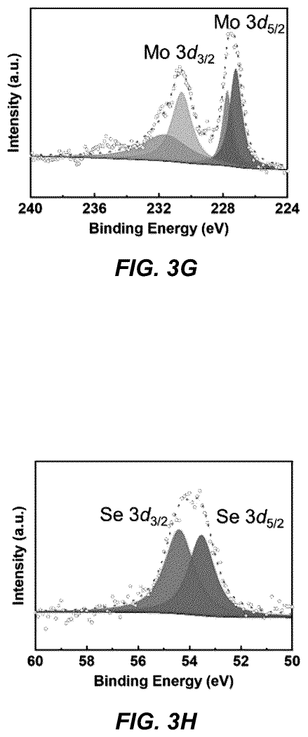

FIG. 3A shows an optical microscope image of a K—MoSe array prepared using the method described above. As shown, the synthesized K—MoSe possesses a straight ribbon-like structure, allowing the K—MoSe to be used as electrodes for two-dimensional (2D) semiconductors. The morphology of the synthesized K—MoSe arrays was characterized by atomic force microscopy (AFM). The AFM image of FIG. 3B shows that the synthesized K—MoSe arrays have a uniform structure with an average thickness of 15.9 nm. The Raman mapping image of FIG. 3C also shows good uniformity and high quality of the synthesized K—MoSe arrays. The Raman spectra shown in FIG. 3D show a strong similarity between each spectrum, indicating that K—MoSe arrays with different thicknesses possess identical structures. As revealed by the cross-section HAADF-STEM image, the K—MoSe nanoarrays have a highly anisotropic atomic structure, which was characterized by angle-resolved polarized Raman spectroscopy (ARPRS), as shown in FIG. 3E. As can be seen in FIG. 3E, all of the peaks attributed to K—MoSe have a highly anisotropic intensity along different directions. The strongest peak of K—MoSe has a fourfold symmetry with four maximum intensities along ˜ 45°, 135°, 225° and 315° (as shown in FIG. 3F), indicating that the synthesized K—MoSe has a highly anisotropic atomic structure, which is consistent with the cross-sectional HAADF-STEM image.

The composition of the synthesized K—MoSe was further characterized by X-ray photoelectron spectroscopy (XPS). As shown in FIG. 3G, the Mo 3d_{5/2} orbital peak can be devaluated into two peaks, which correspond to the 3d_{5/2} orbital peaks of Mo⁺ and Mo²⁺, respectively. Similarly, the Mo 3d_{3/2} orbital peak can also be devaluated into two peaks to Mo⁺ (eV) and Mo²⁺ (eV), respectively, and the mixed valence state of Mo⁺ and Mo²⁺ derives from the intercalation of potassium ions. The XPS Se 3d and K 2p peaks corresponding to Se²⁺ and K⁺ are also visible in FIGS. 3H and 3I, respectively, confirming the successful synthesis of K—MoSe.

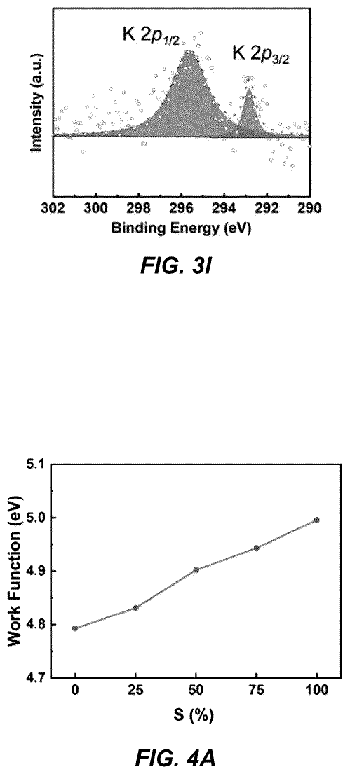

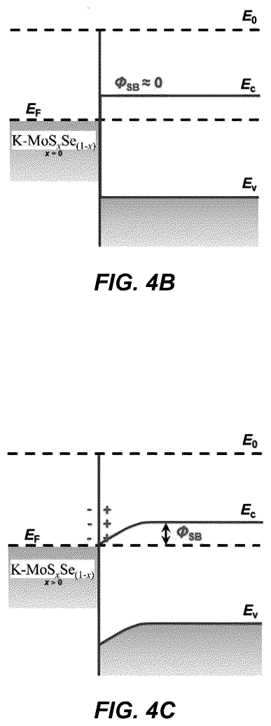

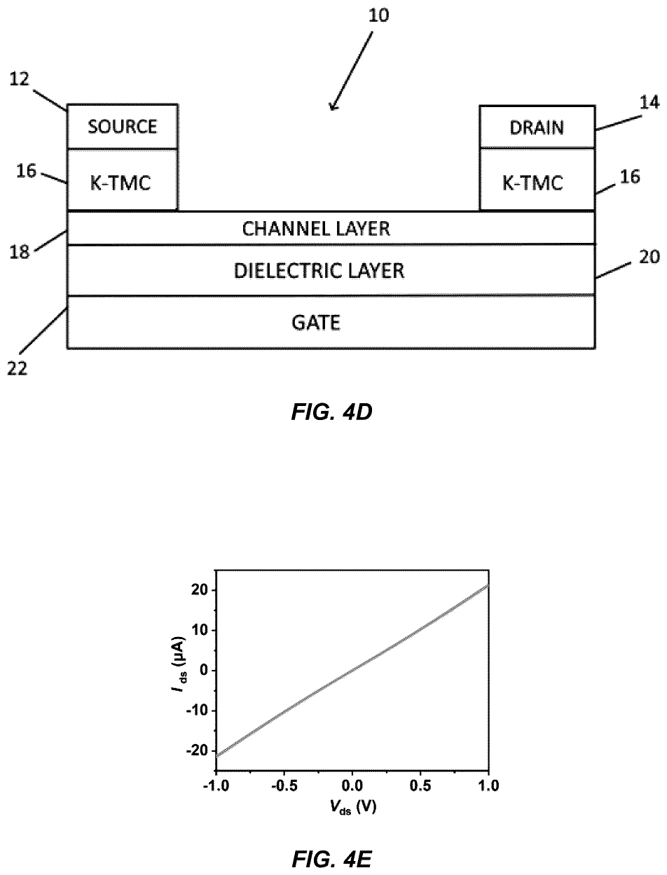

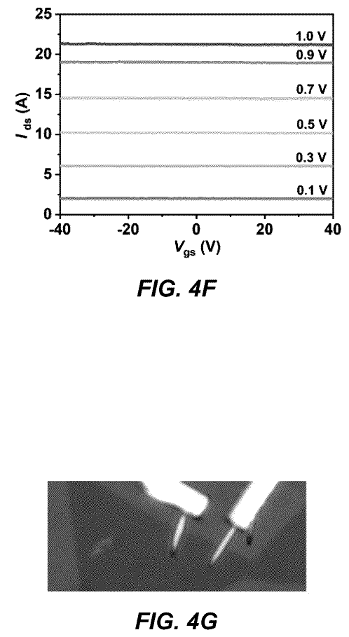

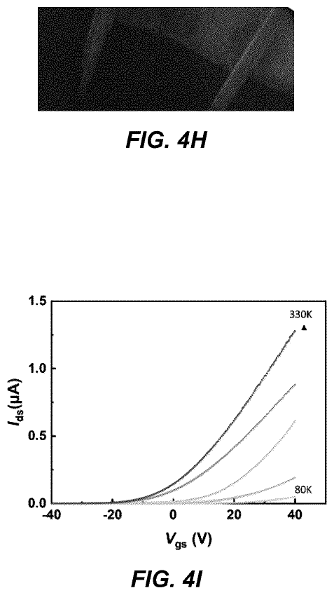

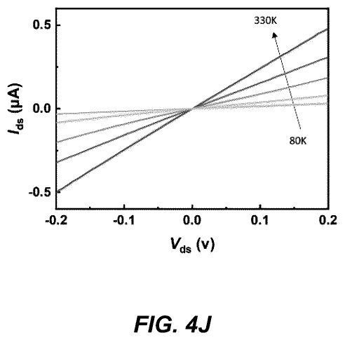

The synthesized K-TMC described above can be used as electrodes for electronics. The device performance is predominant by the ϕ_{SB} at the interface between K-TMC and TMDs, which are highly dependent on the work function difference between K-TMC and TMDs. To realize the tunning of the work function of K-TMC, the composition of K—MoSeₓS₍₁₋ₓ₎ was continuously modulated. As shown in FIG. 4A, the work function of K—MoSₓSe₍₁₋ₓ₎ can be continuously tuned from 4.79±0.01 eV (x=0) to 4.99±0.01 eV (x=1.00). Then, the most commonly used 2D semiconducting TMDs (e.g., 1H-MoS₂ with a work function of 4.78 Ev) were selected as the channel material. For purposes of testing, as shown in FIG. 4D, a sample field effect transistor (FET) 10 was prepared with conventional sources and drains 12, 14, respectively, a conventional dielectric layer 20 and a conventional gate 22. Channel layer 18 was formed from 1H-MoS₂ and the electrodes 16 were prepared from K—MoSₓSe₍₁₋ₓ₎. As shown in FIG. 4B, if K—MoSe (x=0) is selected as the electrode 16, a near ohmic contact is realized, since the work function difference between K—MoSeₓS₍₁₋ₓ₎ and TMDs is around 0 eV. However, when x>0, the work function difference between K—MoSeₓS₍₁₋ₓ₎ (>0) and TMDs becomes larger as x increases, leading to a Schottky contact, as illustrated in FIG. 4C. Thus, in the experiments, the K—MoSe was selected as the metallic electrodes 16 to be integrated with MoS₂ (as the channel layer 18) for the ohmic-contact FET 10.

The metallic character of the synthesized K—MoSe was studied. The I_{ds}−V_{ds} and the output curves of K—MoSe (shown in FIGS. 4E and 4F, respectively) show a linear feature and no gate response, indicating that the synthesized K—MoSe nanowires are metallic. The synthesized K—MoSe nanowires were then transferred onto 1H-MoS₂ synthesized via CVD to form a K—MoSe-MoS₂ heterostructure, as shown in FIGS. 4G and 4H. As shown in FIG. 4I, the FET 10 based on the K—MoSe-MoS₂ heterostructure demonstrates a typical character of an n-type semiconductor. As shown in the variable-temperature transfer curves of FIG. 4J, the FETs not only demonstrate a linear feature at a high temperatures (300 K) but also demonstrate the linear feature at a temperature as low as 80 K, indicating a perfect ohmic contact between the K—MoSe and MoS₂.

It is to be understood that the method of making flat potassium-intercalated metallic transition metal chalcogen nanoarrays is not limited to the specific embodiments described above, but encompasses any and all embodiments within the scope of the generic language of the following claims enabled by the embodiments described herein, or otherwise shown in the drawings or described above in terms sufficient to enable one of ordinary skill in the art to make and use the claimed subject matter.

1. A method of making flat potassium-intercalated metallic transition metal chalcogen nanoarrays, comprising:
mixing a powdered transition metal dichalcogenide with potassium carbonate to form a mixture;
loading the mixture into a crucible and covering the crucible with a substrate;
heating the crucible in a chemical vapor deposition tube furnace to form a potassium-intercalated metallic transition metal chalcogen nanoarray on the substrate through chemical vapor deposition;
removing the substrate and the potassium-intercalated metallic transition metal chalcogen nanoarray formed thereon from the chemical vapor deposition tube furnace; and
washing absorbed salts from the substrate and the potassium-intercalated metallic transition metal chalcogen nanoarray formed thereon.

2. The method of making flat potassium-intercalated metallic transition metal chalcogen nanoarrays as recited in claim 1, wherein the powdered transition metal dichalcogenide is selected from the group consisting of MoS₂, MoSe₂, MoSₓSe₍₁₋ₓ₎, MoTe₂, WSe₂ and WTe₂, where x ranges between 0 and 1.

3. The method of making flat potassium-intercalated metallic transition metal chalcogen nanoarrays as recited in claim 1, further comprising the steps of:
evacuating an atmosphere inside the chemical vapor deposition tube furnace prior to the heating of the crucible therein; and
filling the chemical vapor deposition tube furnace with a gaseous mixture of hydrogen and argon after the evacuation of the atmosphere therefrom and prior to the heating of the crucible therein.

4. The method of making flat potassium-intercalated metallic transition metal chalcogen nanoarrays as recited in claim 3, wherein the chemical vapor deposition tube furnace is filled with the hydrogen at a rate of 10 sccm and the chemical vapor deposition tube furnace is filled with the argon at a rate of 90 sccm.

5. The method of making flat potassium-intercalated metallic transition metal chalcogen nanoarrays as recited in claim 1, wherein the crucible is heated in the chemical vapor deposition tube furnace at a temperature between 850° C. and 900° C.

6. The method of making flat potassium-intercalated metallic transition metal chalcogen nanoarrays as recited in claim 5, wherein the crucible is heated in the chemical vapor deposition tube furnace at the temperature between 850° C. and 900° C. for 10 minutes.

7. The method of making flat potassium-intercalated metallic transition metal chalcogen nanoarrays as recited in claim 1, wherein the substrate comprises a mica substrate.

8. An electrode made using the method according to claim 1.

9. The electrode according to claim 8, wherein the powdered transition metal dichalcogenide is selected from the group consisting of MoS₂, MoSe₂, MoSₓSe₍₁₋ₓ₎, MoTe₂, WSe₂ and WTe₂, where x ranges between 0 and 1.
